(19) United States
(12) Patent Application Publication
(10) Pub. No.: US 2024/0260255 A1
(43) Pub. Date: Aug. 1, 2024

(54) SEMICONDUCTOR DEVICE

(71) Applicant: Kioxia Corporation, Tokyo (JP)

(72) Inventor: Kotaro NODA, Yokkaichi (JP)

(73) Assignee: Kioxia Corporation, Tokyo (JP)

(21) Appl. No.: 18/423,164

(22) Filed: Jan. 25, 2024

(30) Foreign Application Priority Data
Jan. 27, 2023 (JP) 2023-011063

(51) Int. Cl. H10B 12/00

(52) U.S. Cl. CPC H10B 12/33; H10B 12/05; H10B 12/50

(57) ABSTRACT

A semiconductor device includes a substrate where a first and a second region are provided, a transistor layer, and a first wiring layer farther from the substrate than the transistor layer. The transistor layer includes, in the first region, oxide semiconductor layers extending in a first direction and arranged in a second direction, a first wiring opposed to oxide semiconductor layers, and gate insulating films. The first wiring layer includes second wirings and connected to one ends of oxide semiconductor layers in the first region. The transistor layer includes cavities arranged in the second or the third direction at first pitches in the second region. The first wiring layer includes a first conductive layer in the second region. Recessed portions arranged in the second direction or the third direction at the first pitches are provided on a surface of the first conductive layer.

### CROSS-REFERENCE TO RELATED APPLICATIONS

This application is based upon and claims the benefit of Japanese Patent Application No. 2023-011063, filed on Jan. 27, 2023, the entire contents of which are incorporated herein by reference.

### BACKGROUND

### Field

Embodiments described herein relate generally to a semiconductor device.

### Description of the Related Art

There has been known a semiconductor device including a plurality of oxide semiconductor layers extending in a first direction and arranged in a second direction intersecting with the first direction, a wiring extending in the second direction and opposed to the plurality of oxide semiconductor layers, and a plurality of gate insulating films provided between the plurality of oxide semiconductor layers and the wiring.

### BRIEF DESCRIPTION OF THE DRAWINGS

FIG. 1 is a schematic circuit diagram illustrating a part of a configuration of a semiconductor device according to a first embodiment;

FIG. 2 is a schematic plan view illustrating a part of the configuration of the semiconductor device;

FIG. 3 is a schematic plan view illustrating a part of the configuration of the semiconductor device;

FIG. 4 is a schematic cross-sectional view illustrating a part of the configuration of the semiconductor device;

FIG. 5 is a schematic cross-sectional view illustrating a part of the configuration of the semiconductor device;

FIG. 6 is a schematic plan view illustrating a part of the configuration of the semiconductor device;

FIG. 7 is a schematic plan view illustrating a part of the configuration of the semiconductor device;

FIG. 8 is a schematic cross-sectional view illustrating a part of the configuration of the semiconductor device;

FIG. 9 is a schematic plan view illustrating a part of the configuration of the semiconductor device;

FIG. 10 is a schematic perspective view illustrating a part of the configuration of the semiconductor device;

FIG. 11 is a schematic cross-sectional view illustrating a part of the configuration of the semiconductor device;

FIG. 12 is a schematic cross-sectional view for describing a method of manufacturing the semiconductor device;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view illustrating a part of a configuration of a semiconductor device according to a comparative example;

FIG. 23 is a schematic perspective view illustrating a part of a configuration of a modification 1 of the semiconductor device according to the first embodiment;

FIG. 24 is a schematic perspective view illustrating a part of a configuration of a modification 2 of the semiconductor device according to the first embodiment;

FIG. 25 is a schematic cross-sectional view illustrating a part of a configuration of a modification 3 of the semiconductor device according to the first embodiment;

FIG. 26 is a schematic cross-sectional view illustrating a part of a configuration of a semiconductor device according to a second embodiment;

FIG. 27 is a schematic perspective view illustrating a part of the configuration of the semiconductor device;

FIG. 28 is a schematic cross-sectional view for describing a method of manufacturing the semiconductor device;

FIG. 29 is a schematic cross-sectional view for describing the manufacturing method;

FIG. 30 is a schematic cross-sectional view for describing the manufacturing method;

FIG. 31 is a schematic cross-sectional view for describing the manufacturing method;

FIG. 32 is a schematic cross-sectional view illustrating a part of a configuration of a modification of the semiconductor device according to the second embodiment; and

FIG. 33 is a schematic cross-sectional view for describing a manufacturing method of a modification of the semiconductor device.

### DETAILED DESCRIPTION

A semiconductor device according to one embodiment comprises: a substrate where a first region and a second region are provided; a transistor layer spaced from the substrate; and a first wiring layer farther from the substrate than the transistor layer. The transistor layer includes, in the first region: a plurality of first oxide semiconductor layers extending in a first direction intersecting with a surface of the substrate and being arranged in a second direction intersecting with the first direction; a first wiring extending in the second direction and being opposed to the plurality of first oxide semiconductor layers; and a plurality of gate insulating films provided between the plurality of first oxide semiconductor layers and the first wiring. The first wiring layer includes a plurality of second wirings arranged in the second direction and electrically connected to respective one ends of the plurality of first oxide semiconductor layers in the first region. The transistor layer includes a plurality of cavities arranged in the second direction or a third direction intersecting with the first direction and the second direction at first pitches in the second region. The first wiring layer includes a first conductive layer in the second region. A plurality of recessed portions arranged in the second direction or the third direction at the first pitches are provided on a surface on a side far from the substrate of the first conductive layer.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor device”, it may mean a die after dicing and may mean a wafer before dicing. In the former case, it may mean a die after packaging and may mean a die before packaging.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion on a substrate side of this configuration. An upper surface and an upper end of a certain configuration mean a surface and an end portion on a side opposite to the substrate of this configuration. A surface intersecting with the X-direction or the Y-direction is referred to as a side surface and the like.

### First Embodiment

### [Circuit Configuration]

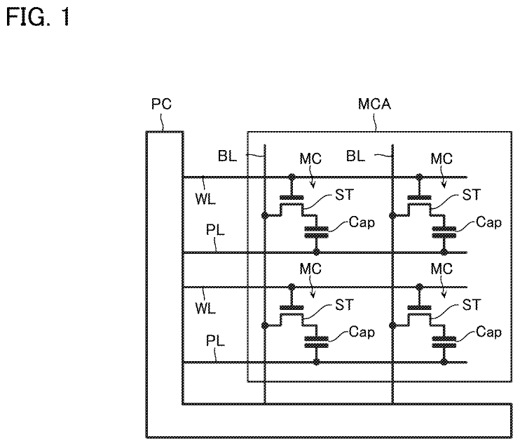

A semiconductor device according to the first embodiment includes, for example, a memory cell array MCA and a peripheral circuit PC as illustrated in FIG. 1.

The memory cell array MCA includes a plurality of bit lines BL, a plurality of word lines WL, a plurality of plate lines PL, and a plurality of memory cells MC that are connected to the plurality of bit lines BL, the plurality of word lines WL, and the plurality of plate lines PL. A plurality of memory cells MC connected to one word line WL are connected to the respective mutually different bit lines BL. A plurality of memory cells MC connected to one bit line BL are connected to the respective mutually different word lines WL.

Each of the memory cells MC includes a select transistor ST and a capacitor Cap that are connected in series between the bit line BL and the plate line PL.

The select transistor ST is a field-effect type transistor including a semiconductor layer that functions as a channel region, a gate insulating film, and a gate electrode. Each gate electrode of the select transistor ST is connected to the word line WL.

The capacitor Cap is a capacitor that includes a pair of electrodes and an insulating film. The capacitor Cap includes a memory portion.

The peripheral circuit PC includes, for example, a voltage generation circuit that generates an operating voltage and outputs the operating voltage to a voltage supply line, a decode circuit that electrically conducts a desired voltage supply line to each of the wirings (the bit lines BL, the word lines WL, and the plate lines PL) in the memory cell array MCA, a sense amplifier circuit that senses a current or a voltage of the bit lines BL, and the like.

### [Structure of Wafer WF]

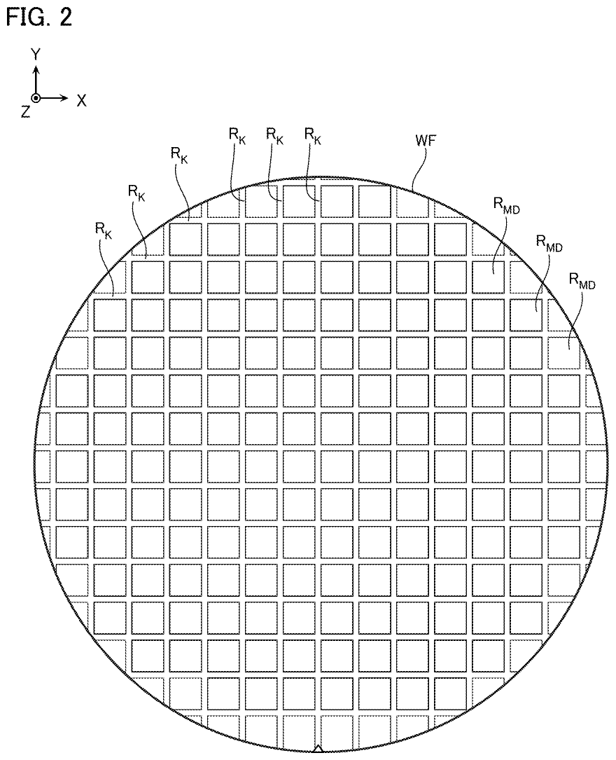

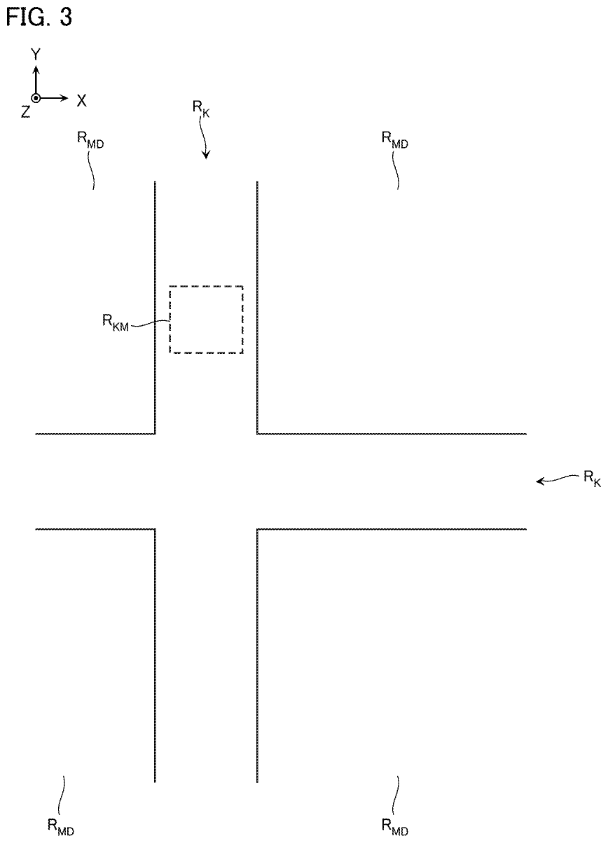

The semiconductor device according to the first embodiment is formed on a wafer WF, for example, as illustrated in FIG. 2. FIG. 3 illustrates an enlarged part of FIG. 2. As illustrated in FIG. 2, a plurality of memory die regions R_{MD} and kerf regions R_{K} provided between these plurality of memory die regions R_{MD} are provided on a surface of the wafer WF. The plurality of memory die regions R_{MD} become memory dies each including a memory cell array MCA and a peripheral circuit PC after dicing. For example, as illustrated in FIG. 3, the kerf region R_{K} includes a marked region R_{K} and other various regions used in manufacturing the memory die. The configurations in the kerf region R_{K} are not used for inputting/outputting a voltage to the memory cell array MCA or inputting/outputting a data signal or other signals to the memory cell array MCA.

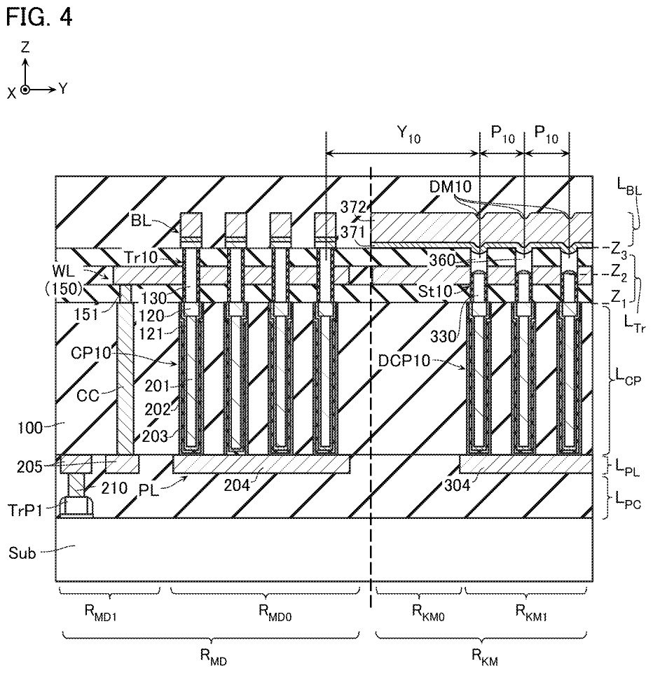

FIG. 4 is a schematic YZ cross-sectional view illustrating a part of a configuration of the semiconductor device. As illustrated in FIG. 4, the semiconductor device according to the first embodiment includes a substrate Sub, a transistor layer L_{Tr} spaced from the substrate Sub in the Z-direction, a bit line layer L_{BL} provided above the transistor layer L_{Tr}, a capacitor layer L_{CP} provided below the transistor layer L_{Tr}, a plate line layer L_{PL} provided below the capacitor layer L_{CP}, and a peripheral circuit layer L_{PC} provided on the substrate Sub below the plate line layer L_{PL}. The substrate Sub contains, for example, P-type silicon (Si) containing P-type impurities, such as boron (B). The substrate Sub may be, for example, a part of the wafer WF (FIG. 2).

FIG. 4 schematically illustrates the memory die region R_{MD} and the marked region R_{KM} illustrated in FIG. 3 on the same cross-sectional surface. The memory die region R_{MD} includes a memory region R_{MD0} and a peripheral region R_{MD1}. The marked region R_{K} includes a region R_{KM0} and a region R_{KM1}.

### [Structure of Memory Die Region R_{MD}]

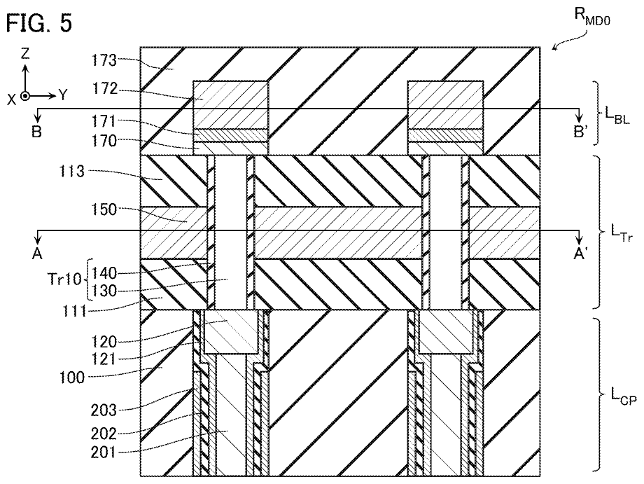

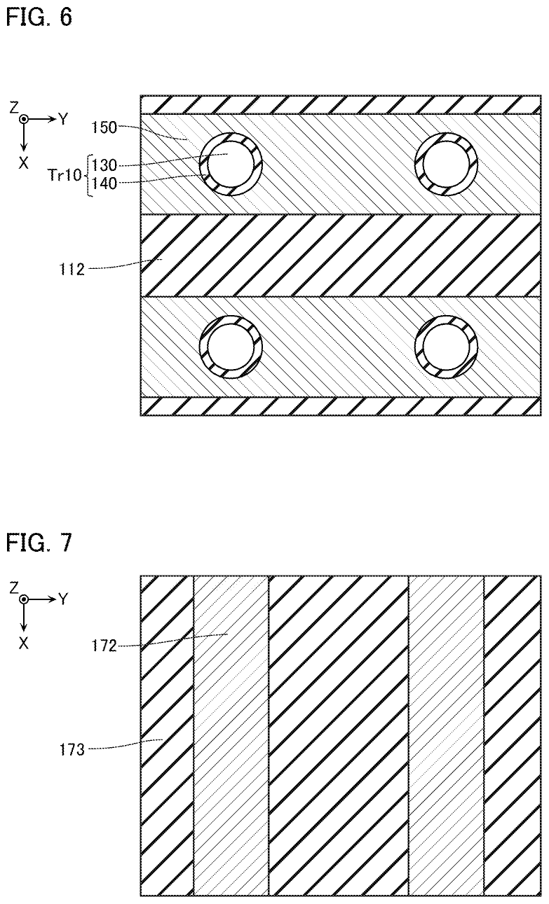

Next, with reference to FIG. 4 to FIG. 7, a structure of the memory die region R_{MD} is described. FIG. 5 is a schematic YZ cross-sectional view illustrating a part of a configuration of the memory region R_{MD}o. FIG. 6 is a schematic XY cross-sectional view of the configuration illustrated in FIG. 5 taken along a line A-A′ viewed in an arrow direction. FIG. 7 is a schematic XY cross-sectional view of the configuration illustrated in FIG. 5 taken along a line B-B′ viewed in an arrow direction.

### [Structure of Memory Region R_{MD0}]

The transistor layer L_{Tr} in the memory region R_{MD0} includes, for example, as illustrated in FIG. 5, an insulating layer 111 provided on an upper surface of the capacitor layer L_{CP} and an insulating layer 113 provided above the insulating layer 111. The transistor layer L_{Tr} in the memory region R_{MD0} includes, for example, as illustrated in FIG. 6, a plurality of insulating layers 112 and a plurality of conductive layers 150 which are provided between the insulating layer 111 and the insulating layer 113 and alternately arranged in the X-direction. The transistor layer L_{Tr} in the memory region R_{MD0} includes, for example, as illustrated in FIG. 6, a plurality of semiconductor layers 130 arranged in the X-direction and the Y-direction corresponding to the plurality of conductive layers 150 and insulating layers 140 provided on outer peripheral surfaces of the semiconductor layers 130. In the following description, these configurations that achieve the select transistor ST (FIG. 1) provided in the transistor layer L_{Tr} of the memory region R_{MD0} are referred to as a “transistor structure Tr10” in some cases. The transistor structure Tr10 includes, for example, the semiconductor layer 130 and the insulating layer 140.

The insulating layer 111, the insulating layer 112, and the insulating layer 113 contain, for example, silicon oxide (SiO₂).

The semiconductor layer 130, for example, extends in the Z-direction and has an approximately columnar shape. The semiconductor layer 130 is an oxide semiconductor, and functions as, for example, a channel region of the select transistor ST (FIG. 1). For example, the semiconductor layer 130 contains at least one element selected from the group consisting of indium (In), gallium (Ga), silicon (Si), aluminum (Al), and tin (Sn), and zinc (Zn) and oxygen (O). The semiconductor layer 130 contains, for example, indium (In), gallium (Ga), zinc (Zn), and oxygen (O).

The insulating layer 140, for example, extends in the Z-direction, and has an approximately cylindrical shape. The insulating layer 140 functions as, for example, a gate insulating film of the select transistor ST (FIG. 1). The insulating layer 140 contains, for example, silicon oxide (SiO₂).

The conductive layer 150 functions as, for example, the gate electrodes of a plurality of the select transistors ST arranged in the Y-direction and the word line WL (FIG. 1) of the memory cell array MCA. The conductive layer 150 may contain, for example, tungsten (W) or a stacked structure of titanium nitride (TiN) and tungsten (W).

The bit line layer L_{BL} in the memory region R_{MD0} includes, for example, as illustrated in FIG. 5, a conductive layer 170, a conductive layer 171, and a conductive layer 172 provided on an upper surface of the transistor layer L_{Tr} in the order. The conductive layer 170, the conductive layer 171, and the conductive layer 172 extend in the X-direction, and a plurality of the conductive layers 170, the conductive layers 171, and the conductive layers 172 are provided to be arranged in the Y-direction, for example, as illustrated in FIG. 5 and FIG. 7. Between the plurality of conductive layers 170, the plurality of conductive layers 171, and the plurality of conductive layers 172 arranged in the Y-direction, and on an upper surface of the conductive layer 172, an insulating layer 173 of silicon oxide (SiO₂) or the like is provided. The conductive layer 170, the conductive layer 171, and the conductive layer 172 are electrically connected to the plurality of semiconductor layers 130 arranged in the X-direction. The conductive layer 170, the conductive layer 171, and the conductive layer 172 function as, for example, source electrodes of the plurality of select transistors ST arranged in the X-direction and the bit lines BL (FIG. 1) of the memory cell array MCA. The conductive layer 170 contains, for example, at least one element selected from the group consisting of indium (In), tin (Sn), niobium (Nb), titanium (Ti), tungsten (W), ruthenium (Ru), tantalum (Ta), iridium (Ir), and molybdenum (Mo). The conductive layer 170 may be, for example, indium tin oxide (InSnO). The conductive layer 171 contains, for example, titanium nitride (TiN). The conductive layer 172 contains, for example, tungsten (W).

For example, as illustrated in FIG. 4 and FIG. 5, the capacitor layer L_{CP} in the memory region R_{MD0} includes a plurality of conductive layers 120 provided corresponding to the plurality of semiconductor layers 130 and connected to respective lower ends of the plurality of semiconductor layers 130, a plurality of conductive layers 201 provided corresponding to these plurality of conductive layers 120 and connected to respective lower ends of the plurality of conductive layers 120, and a plurality of conductive layers 121 provided on outer peripheral surfaces of these plurality of conductive layers 120 and outer peripheral surfaces and lower surfaces of the plurality of conductive layers 201. The capacitor layer L_{CP} includes insulating layers 202 provided on outer peripheral surfaces and lower surfaces of the conductive layers 121 and conductive layers 203 provided on outer peripheral surfaces and lower surfaces of the insulating layers 202 (FIG. 4). In the following description, these configurations that achieve the capacitor Cap (FIG. 1) provided in the capacitor layer L_{CP} of the memory region R_{MD0} are referred to as a “capacitor structure CP10” in some cases. The capacitor structure CP10 includes, for example the conductive layer 120, the conductive layer 121, the conductive layer 201, the insulating layer 202, and the conductive layer 203. Between a plurality of the capacitor structures CP10, for example, an insulating layer 100 of silicon oxide (SiO₂) or the like is provided.

The conductive layer 120 functions as, for example, a drain electrode of the select transistor ST (FIG. 1) and a part of one electrode of the capacitor Cap (FIG. 1). The conductive layer 120 has an approximately circular shape in an XY cross-sectional surface, and may have a plug shape. The conductive layer 120 contains, for example, a material similar to that of the conductive layer 170. The conductive layer 120 may be, for example, indium tin oxide (InSnO).

The conductive layer 121 functions as, for example, apart of the one electrode of the capacitor Cap (FIG. 1). The conductive layer 121 may be, for example, titanium nitride (TiN).

The conductive layer 201 functions as a part of the one electrode of the capacitor Cap (FIG. 1). The conductive layer 201 includes, for example, a stacked structure of titanium nitride (TiN) and tungsten (W).

The insulating layer 202 functions as an insulating layer between the electrodes of the capacitor Cap (FIG. 1). The insulating layer 202 contains, for example, alumina (Al₂O₃). The insulating layer 202 may be, for example, silicon oxide (SiO₂) or another insulating metal oxide.

The conductive layer 203 functions as, for example, the other electrode of the capacitor Cap (FIG. 1). The conductive layer 203 includes, for example, a stacked structure of titanium nitride (TiN) and tungsten (W).

For example, as illustrated in FIG. 4, the plate line layer L_{PL} in the memory region R_{MD0} includes a conductive layer 204 provided on a lower surface of the capacitor layer L_{CP}. The conductive layer 204 is electrically connected to a plurality of the conductive layers 203. The conductive layer 204 functions as, for example, a plate line PL (FIG. 1). The conductive layer 204 may contain, for example, tungsten (W) or a stacked structure of titanium nitride (TiN) and tungsten (W).

### [Structure of Peripheral Region R_{MD1}]

For example, as illustrated in FIG. 4, the transistor layer L_{Tr} in the peripheral region R_{MD1} includes a part of the conductive layer 150 that functions as a word line WL and an electrode 151 connected to a lower end of the conductive layer 150. The electrode 151 may contain, for example, tungsten (W) or a stacked structure of titanium nitride (TiN) and tungsten (W).

For example, as illustrated in FIG. 4, the capacitor layer L_{CP} in the peripheral region R_{MD1} includes a plurality of electrodes CC extending in the Z-direction. For example, the electrode CC has an upper end electrically connected to the electrode 151 and a lower end electrically connected to a part of a plurality of conductive layers 205 (described later) in the plate line layer L_{PL}. The electrode CC may contain, for example, tungsten (W) or a stacked structure of titanium nitride (TiN) and tungsten (W).

For example, as illustrated in FIG. 4, the plate line layer L_{PL} in the peripheral region R_{MD1} includes a plurality of conductive layers 205. The conductive layer 205 may contain, for example, a material similar to that of the conductive layer 204.

For example, as illustrated in FIG. 4, the peripheral circuit layer L_{PC} in the peripheral region R_{MD1} includes a plurality of transistors TrP1 provided on the substrate Sub and a plurality of electrodes 210 connected to the plurality of transistors TrP1. The plurality of electrodes 210 have upper ends connected to the conductive layers 205. The respective plurality of electrodes 210 are connected to source regions, drain regions, gate electrodes, and the like of the plurality of transistors TrP1. The plurality of transistors TrP1 constitute, for example, the peripheral circuit PC (FIG. 1).

### [Structure of Marked Region R_{KM}]

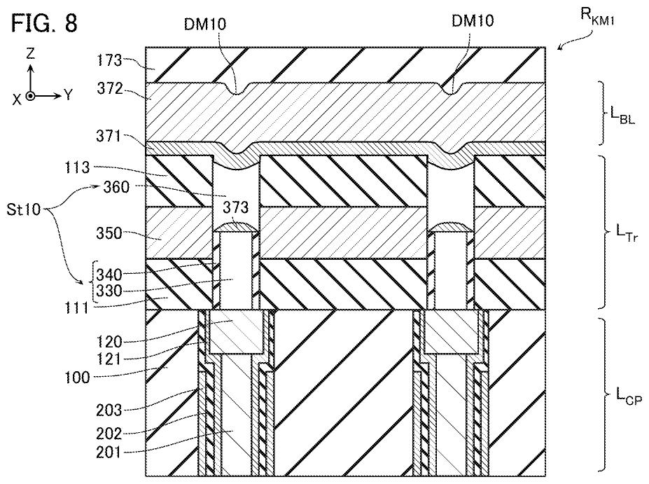

Next, with reference to FIG. 4 and FIG. 8, a structure of the marked region R_{KM} is described. FIG. 8 is a schematic YZ cross-sectional view illustrating a part of the configuration in the region R_{KM1}.

### [Structure of Region R_{KM1}]

For example, as illustrated in FIG. 8, the transistor layer L_{Tr} in the region R_{KM1} is basically configured similarly to the transistor layer L_{Tr} (FIG. 5) in the memory region R_{MD0}.

However, the transistor layer L_{Tr} in the region R_{KM1} includes a semiconductor layer 330, an insulating layer 340, and a conductive layer 350 instead of the semiconductor layer 130, the insulating layer 140, and the conductive layer 150. Further, the transistor layer L_{Tr} in the region R_{KM1} includes a cavity 360 between the semiconductor layer 330 and the bit line layer L_{BL}. For example, as illustrated in FIG. 8, a conductive layer 373 may be provided on upper surfaces of the semiconductor layer 330 and the insulating layer 340. In the following description, a structure provided in the transistor layer L_{Tr} in the region R_{KM1} is referred to as a “structure St10” in some cases. The structure St10 includes, for example, the semiconductor layer 330, the insulating layer 340, and the cavity 360.

The semiconductor layer 330, for example, extends in the Z-direction, and has an approximately columnar shape. The semiconductor layer 330 is formed in a process same as the semiconductor layer 130, and contains a material similar to that of the semiconductor layer 130. For example, as illustrated in FIG. 4, the semiconductor layer 330 has a length in the Z-direction smaller than a length in the Z-direction of the semiconductor layer 130. For example, one end portion on a substrate Sub side of the semiconductor layer 330 and one end portion on the substrate Sub side of the semiconductor layer 130 are provided at a position Z₁ so as to be approximately equal from the substrate Sub. Meanwhile, a position Z₂ on a bit line layer L_{BL} side of the other end portion of the semiconductor layer 330 is provided at a position closer to the substrate Sub than a position Z₃ of the other end portion on the bit line layer L_{BL} side of the semiconductor layer 130. A Length in the X-direction or the Y-direction of the semiconductor layer 330 may be approximately same as or larger than a length in the X-direction or the Y-direction of the semiconductor layer 130. The semiconductor layer 330 does not function as a channel region of the select transistor ST (FIG. 1).

The insulating layer 340 (FIG. 8) is formed in a process same as the insulating layer 140 (FIG. 5), and contains a material similar to that of the insulating layer 140. For example, as illustrated in FIG. 4, a length in the Z-direction of the insulating layer 340 is smaller than a length in the Z-direction of the insulating layer 140. The insulating layer 340 does not function as a gate insulating film of the select transistor ST (FIG. 1).

The conductive layer 350 (FIG. 8) is formed in a process same as the conductive layer 150 (FIG. 5), and contains a material similar to that of the conductive layer 150. The conductive layer 350 does not function as the gate electrode of the select transistor ST or the word line WL (FIG. 1) of the memory cell array MCA.

For example, as illustrated in FIG. 8, the cavity 360 is provided at a position corresponding to the insulating layer 113 and the conductive layer 350 in the Z-direction. The cavity 360 has an inner wall surface surrounded by the insulating layer 113 and the conductive layer 350. The cavity 360 has a bottom surface and an upper surface surrounded by the conductive layer 373 and the conductive layer 371. The cavity 360 means what is called a space surrounded by solid materials provided around the part provided with the cavity 360, and the part provided with the cavity 360 does not contain any of the solid materials. The cavity 360 is a space containing, for example, air of a mixture of a plurality of gases, such as nitrogen, oxygen, and a noble gas. The cavity 360 may be degassed so as not to contain any gas.

The conductive layer 373 is formed in a process same as the conductive layer 171 and the conductive layer 371, and contains a material similar to that of the conductive layer 171.

For example, as illustrated in FIG. 8, the bit line layer L_{BL} in the region R_{KM1} includes a conductive layer 371 and a conductive layer 372 provided on the upper surface of the transistor layer L_{Tr} in the order. The conductive layer 371 and the conductive layer 372 extend, for example, the X-direction and the Y-direction. A plurality of recessed portions DM10 are provided on an upper surface of the conductive layer 372 in the region R_{K1}. The plurality of recessed portions DM10 are provided at positions corresponding to the plurality of cavities 360. The plurality of recessed portions DM10 are provided at positions, for example, at least partially overlapping with the plurality of cavities 360 viewed in the Z-direction.

The conductive layer 371 and the conductive layer 372 are formed in processes same as the conductive layer 171 and the conductive layer 172, respectively, and contain materials similar to those of the conductive layer 171 and the conductive layer 172. The conductive layer 371 and the conductive layer 372 do not function as the source electrode of the select transistor ST and the bit line BL (FIG. 1) of the memory cell array MCA.

The capacitor layer L_{CP} in the region R_{KM1} may include, for example, structures DCP10 similar to the plurality of capacitor structures CP10 (FIG. 4). The structure DCP10 is provided as a dummy, and does not function as the capacitor Cap (FIG. 1).

For example, as illustrated in FIG. 4, the plate line layer L_{PL} in the region R_{KM1} may include a conductive layer 304 provided on a lower surface of the capacitor layer L_{CP}. The conductive layer 304 does not function as the plate line PL. The conductive layer 304 contains, for example, a material similar to that of the conductive layer 204.

### [Structure of Region R_{KM0}]

For example, as illustrated in FIG. 4, the transistor layer L_{Tr} in the region R_{KM0} is not provided with the transistor structure Tr10 or the structure St10.

For example, as illustrated in FIG. 4, the bit line layer L_{BL} in the region R_{KM0} is basically configured similarly to the bit line layer L_{BL} in the region R_{KM1}. However, the conductive layer 372 in the region R_{KM0} has an upper surface approximately flat and not provided with the recessed portion DM10.

The capacitor layer L_{CP} in the region R_{KM0} is not provided with the structure DCP10.

### [Exemplary Configuration of Marked Region R_{KM}]

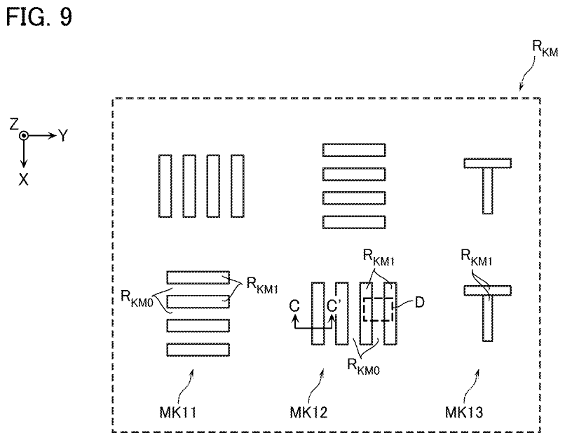

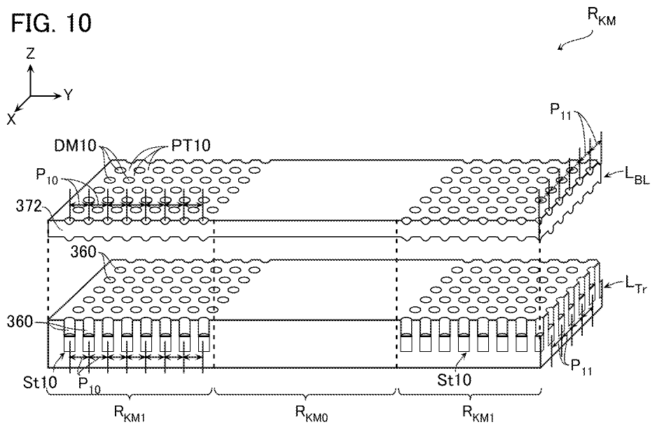

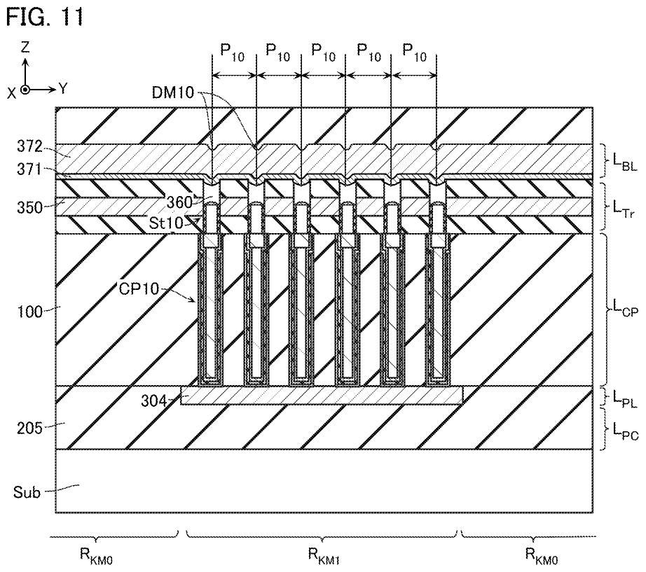

Next, with reference to FIG. 9 to FIG. 11, an exemplary configuration of the marked region R_{KM} is described. FIG. 9 is a schematic plan view illustrating a part of a configuration of the marked region R_{KM} (FIG. 3). FIG. 10 is a schematic perspective view illustrating an enlarged region D illustrated in FIG. 9. FIG. 11 is a schematic YZ cross-sectional view of the configuration illustrated in FIG. 9 taken along a line C-C′ viewed in an arrow direction.

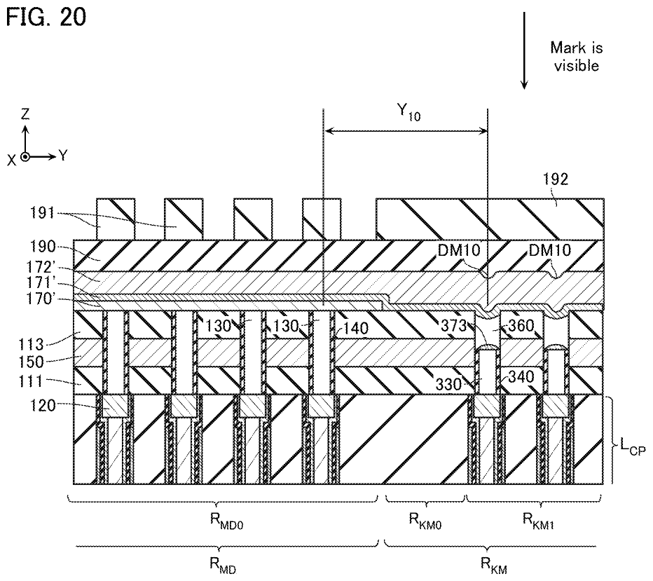

The marked region R_{KM} includes a mark MK11, a mark MK12, and a mark MK13, for example, as illustrated in FIG. 9. These mark MK11, mark MK12, and mark MK13 function as, for example, alignment marks in a manufacturing process (FIG. 20) of the semiconductor device described later.

The mark MK11 is a line group in which a plurality of regions R_{KM1} extending in the Y-direction are arranged in the X-direction at constant intervals. The mark MK12 is a line group in which a plurality of regions R_{KM1} extending in the X-direction are arranged in the Y-direction at constant intervals. The mark MK13 is a T-shaped mark in which the region R_{KM1} extending in the X-direction is combined with the region R_{KM1} extending in the Y-direction.

In the marked region R_{KM}, the region R_{KM0} described with reference to FIG. 4 and the like is provided excluding the positions where the regions R_{KM1} are provided. For example, as illustrated in FIG. 9, the regions R_{KM0} are provided between the respective regions R_{KM1} included in the mark MK11, the mark MK12, and the mark MK13. Further, the regions R_{KM0} are provided between the mark MK11, the mark MK12, and the mark MK13.

FIG. 10 schematically illustrates a relation between the structure in the transistor layer L_{Tr} and the structure in the bit line layer L_{BL} in the two regions R_{KM1} adjacent in the Y-direction and the region R_{KM0} arranged therebetween. FIG. 11 illustrates the structure in a YZ cross-sectional surface of the two regions R_{KM0} adjacent in the Y-direction and the region R_{K}i arranged therebetween.

In the transistor layer L_{Tr} in the region R_{KM1}, as illustrated in FIG. 10 and FIG. 11, a plurality of the structures St10 are provided to be arranged in the Y-direction at pitches P₁₀. Each of the structures St10 includes the cavity 360 (FIG. 8) in its upper portion, and these plurality of cavities 360 are similarly arranged in the Y-direction at the pitches P₁₀. When the conductive layer 371 and the conductive layer 372 are formed at the upper portions of the plurality of cavities 360, the conductive layer 371 and the conductive layer 372 partially enter the plurality of cavities 360 side during the film formation. Therefore, in the region R_{KM1}, recessed portions and projecting portions are formed on upper surfaces and lower surfaces of the conductive layer 371 and the conductive layer 372 corresponding to the pitches P₁₀ at which the plurality of cavities 360 are arranged. In this case, for example, as illustrated in FIG. 10 and FIG. 11, a plurality of the recessed portions DM10 are formed to be arranged in the Y-direction at the pitches P₁₀ at the upper surface of the conductive layer 372 in the region R_{KM1}. The recessed portion DM10 has, for example, an approximately circular shape in an XY cross-sectional surface.

In the transistor layer L_{Tr} in the region R_{KM1} (FIG. 10), a plurality of the structures St10 (FIG. 8) may be provided to be arranged int the X-direction at pitches P₁₁. In this case, for example, as illustrated in FIG. 10, a plurality of the recessed portions DM10 are formed to be arranged in the Y-direction at the pitches P₁₀ and in the X-direction at the pitches P₁₁ at the upper surface of the conductive layer 372. The pitch P₁₁ and the pitch P₁₀ may be same, or may be different.

In the transistor layer L_{Tr} in the region R_{KM0} (FIG. 10), the structure St10 is not provided. When the conductive layer 371 and the conductive layer 372 are formed at an upper portion of the transistor layer L_{Tr} in the region R_{KM0}, the recessed portion or the projecting portion is not formed on the upper surfaces and the lower surfaces of the conductive layer 371 and the conductive layer 372, and the conductive layer 371 and the conductive layer 372 are formed to be approximately flat.

For example, as illustrated in FIG. 10, at the upper surface of the conductive layer 372 in the region R_{KM1}, respective flat portions provided to be alternately arranged with the plurality of recessed portions DM10 in the X-direction or the Y-direction are referred to as a plurality of flat portions PT10. The plurality of recessed portions DM10 are provided at positions closer to the substrate than the plurality of flat portions PT10.

In the marked region R_{KM}, the plurality of recessed portions DM10 are arranged in at least one direction of the X-direction and the Y-direction at the upper surface of the conductive layer 372 in the region R_{KM1}. Meanwhile, the upper surface of the conductive layer 372 in the region R_{KM0} is formed to be approximately flat. Between the upper surface in the region R_{KM1} and the upper surface in the region R_{KM0}, reflection and diffusion characteristics to a project light from above are different. Accordingly, when the conductive layer 372 in the marked region R_{KM} is observed from above, the respective regions R_{KM1} can be visually perceived as lines constituting the various marks in macroscopic view.

### [Manufacturing Method of First Embodiment]

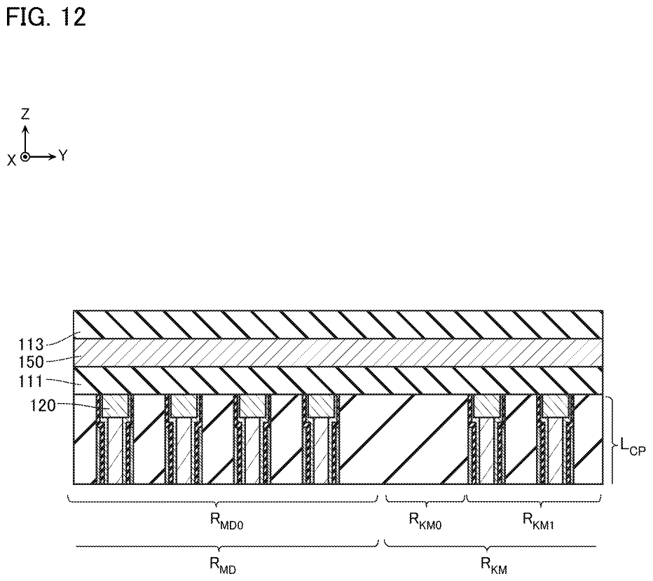

Next, with reference to FIG. 12 to FIG. 21, a method of manufacturing the semiconductor device according to the embodiment is described. FIG. 12 to FIG. 21 are schematic cross-sectional views for describing the method of manufacturing the semiconductor device according to the first embodiment. For convenience of explanation, FIG. 12 to FIG. 21 illustrate the memory region R_{MD0} in the memory die region R_{MD} and the marked region R_{KM} in the same cross-sectional view.

In the manufacturing method, the peripheral circuit layer L_{PC}, the plate line layer L_{PL}, and the capacitor layer L_{CP} (FIG. 4) are formed above the substrate Sub (not illustrated) in the order. Next, for example, as illustrated in FIG. 12, on the upper surface of the capacitor layer L_{CP}, the insulating layer 111, the conductive layer 150 and the insulating layer 112 (FIG. 6), and the insulating layer 113 are formed in the order. This process is performed by, for example, Chemical Vapor Deposition (CVD).

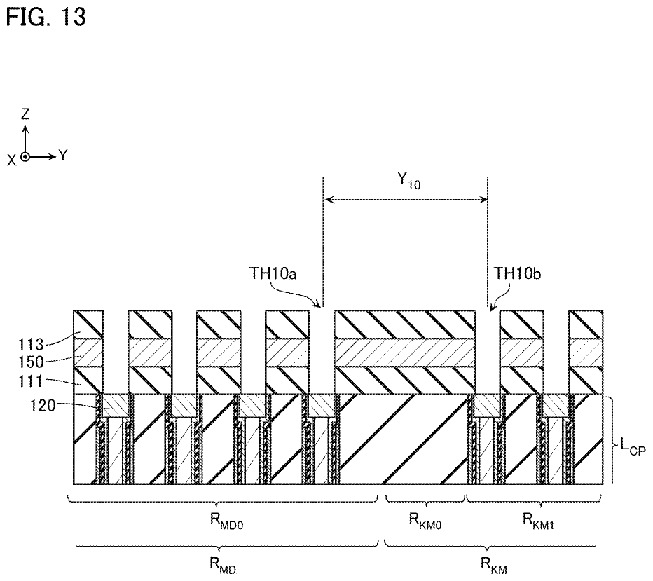

Next, for example, as illustrated in FIG. 13, openings TH10a are formed at positions corresponding to the conductive layers 120 in the memory region R_{MD0}, and openings TH10b are formed at positions corresponding to the conductive layers 120 in the region R_{KM1}. The opening TH10a and the opening TH10b extend in the Z-direction, penetrate the insulating layer 113, the conductive layer 150, and the insulating layer 111, and exposes the conductive layer 120. This process is performed by, for example, Reactive Ion Etching (RIE). Note that in this process, since the openings TH10a and the openings TH10b are formed at once, misalignment does not occur in the positional relation between the opening TH10a and the opening TH10b. For example, as illustrated in FIG. 13, a distance Y₁₀ between the opening TH10a and the opening TH10b is determined.

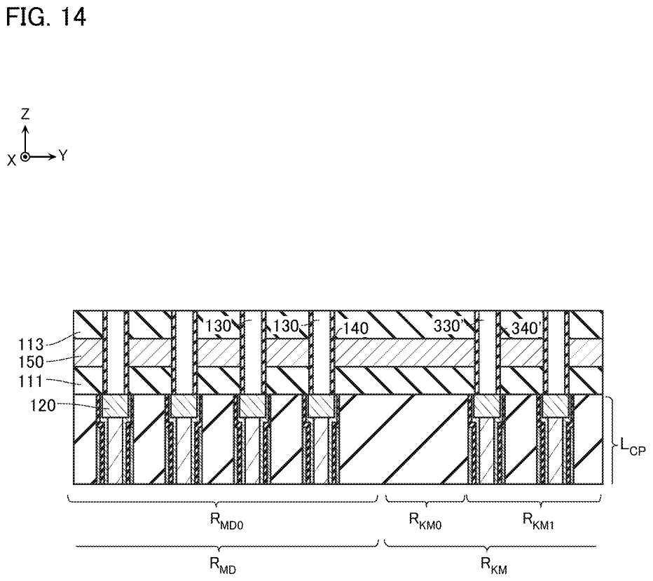

Next, for example, as illustrated in FIG. 14, an insulating layer containing a material similar to that of the insulating layer 140 and the insulating layer 340 is formed on inner side surfaces and bottom surfaces of the openings TH10a and the openings TH10b, and subsequently, the portion formed on the bottom surfaces of the openings TH10a and the openings TH10b is removed, thus forming the insulating layer 140 and an insulating layer 340′ on the inner side surfaces of the openings TH10a and the openings TH10b. Further, the semiconductor layer 130 and a semiconductor layer 330′ are formed inside the openings TH10a and the openings TH10b. The insulating layer 340′ and the semiconductor layer 330′ contain, for example, materials similar to those of the insulating layer 140 and the semiconductor layer 130. The process of forming the insulating layer 140 and the insulating layer 340′ is performed by, for example, Atomic Layer Deposition (ALD), CVD, or the like, and RIE or the like. The process of forming the semiconductor layer 130 and the semiconductor layer 330′ is performed by, for example, ALD, CVD, or the like, and Chemical Mechanical Planarization (CMP) or the like.

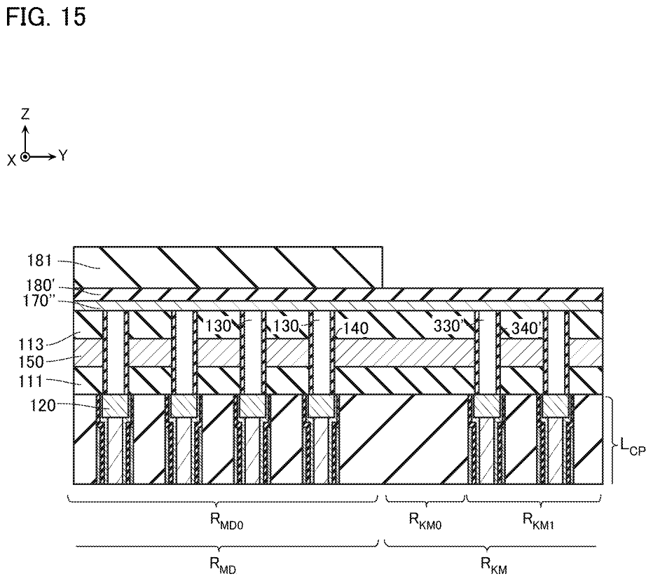

Next, for example, as illustrated in FIG. 15, a conductive layer 170″ and an insulating layer 180′ are formed on an upper surface of a structure illustrated in FIG. 14. Further, a mask material 181, such as a resist, is formed on an upper surface of the insulating layer 180′ excluding the marked region R_{KM}. The conductive layer 170″ contains, for example, a material similar to that of the conductive layer 170. The insulating layer 180′ contains, for example, silicon oxide (SiO₂). The process of forming the conductive layer 170′¹′ and the insulating layer 180′ is performed by, for example, CVD. The process of forming the mask material 181 is performed by, for example, applying a resist material and patterning by photolithography or the like.

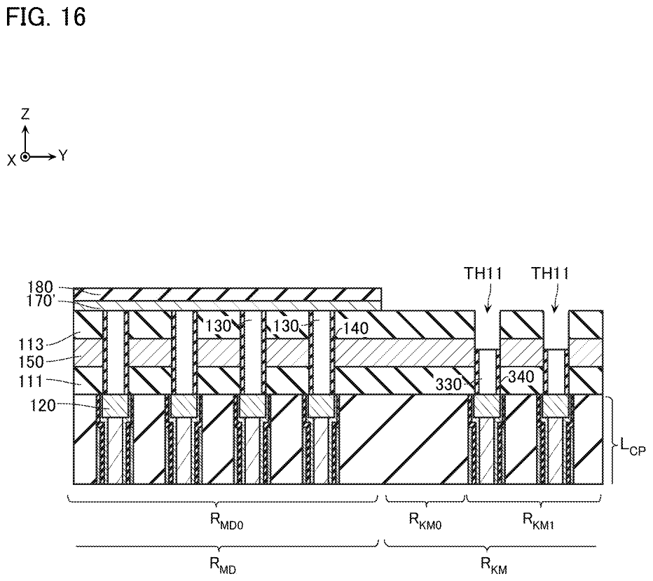

Next, for example, as illustrated in FIG. 16, in the marked region R_{KM} not covered with the mask material 181, a part of the insulating layer 180′, a part of the conductive layer 170″, a part of the semiconductor layer 330′, and a part of the insulating layer 340′ are removed. Through this process, the semiconductor layer 330 and the insulating layer 340 are formed in the region R_{KM1}, and a conductive layer 170′ and an insulating layer 180 are formed in the memory region R_{MD0}. The conductive layer 170′ and the insulating layer 180 contain, for example, materials similar to those of the conductive layer 170″ and the insulating layer 180′. Further, in this process, openings TH11 are formed above the semiconductor layer 330 and the insulating layer 340. This process is performed by, for example, RIE.

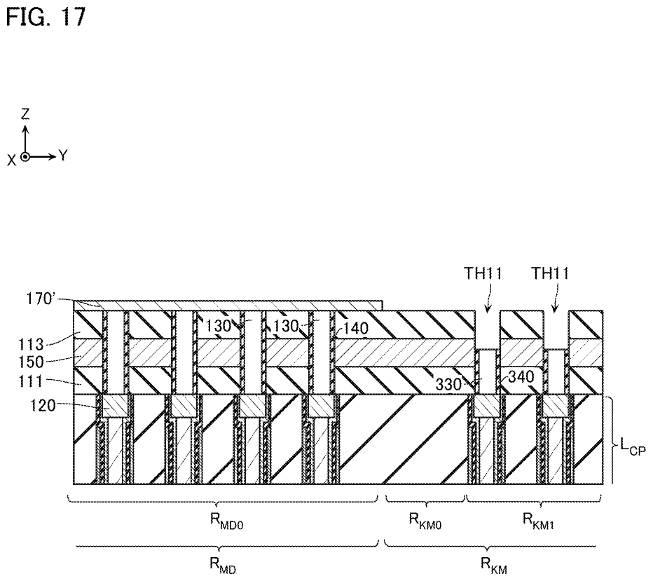

Next, for example, as illustrated in FIG. 17, the insulating layer 180 is removed. This process is performed by, for example, wet etching.

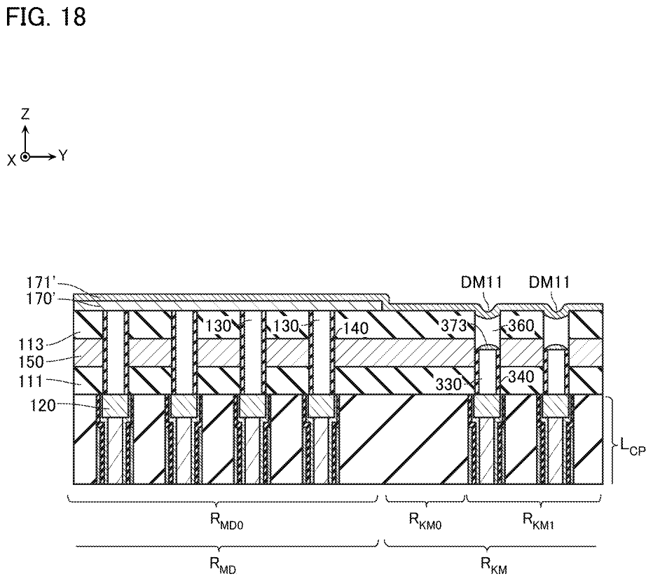

Next, for example, as illustrated in FIG. 18, a conductive layer 171′ is formed on an upper surface of the conductive layer 170′ in the memory region R_{MD0} and an upper surface of the insulating layer 113 and upper portions of the openings TH11 in the marked region R_{KM}. The conductive layer 171′ contains, for example, a material similar to that of the conductive layer 171. Note that in this process, as illustrated in FIG. 18, while a part of the conductive layer 171′ enters inside the opening TH11, the opening TH11 is not completely filled with the conductive layer 171′, and the upper portion of the opening TH11 is closed by the conductive layer 171′. Thus, the recessed portion DM11 as illustrated in FIG. 18 is formed at a portion of the conductive layer 171′ above the portion at which the opening TH11 is provided. Further, the cavity 360 is formed above the semiconductor layer 330 and the insulating layer 340. Note that in this process, at an early stage of forming the conductive layer 171′, a film of a material similar to that of the conductive layer 171′ may be slightly formed on a bottom surface of the opening TH11. In this case, the conductive layer 373 containing a material similar to that of the conductive layer 171′ is formed on upper surfaces of the semiconductor layer 330 and the insulating layer 340. This process is performed by, for example, ALD or CVD.

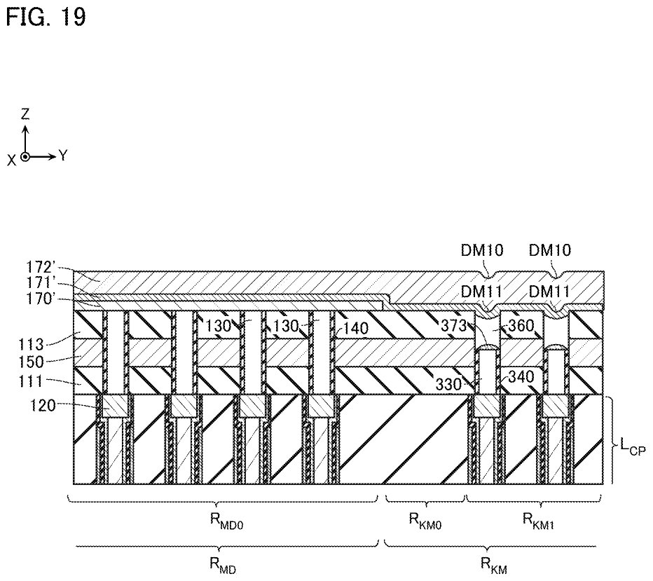

Next, for example, as illustrated in FIG. 19, a conductive layer 172′ is formed on an upper surface of the conductive layer 171′. The conductive layer 172′ contains, for example, a material similar to that of the conductive layer 172. In this process, the conductive layer 172′ is formed to have a relatively uniform film thickness. Thus, in the region R_{KM1}, the plurality of recessed portions DM10 are formed on an upper surface of the conductive layer 172′ so as to follow shapes of the plurality of recessed portions DM11 provided on the upper surface of the conductive layer 171′. This process is performed by, for example, CVD.

Next, for example, as illustrated in FIG. 20, an insulating layer 190 of silicon oxide (SiO₂) or the like is formed on the upper surface of the conductive layer 172′. Further, on an upper surface of the insulating layer 190, a mask material 191, such as a resist, to cover positions corresponding to the bit lines BL is formed in the memory region R_{MD0}, and a mask material 192, such as a resist, to cover the marked region R_{KM} is formed in the region R_{KM1}. The process of forming the insulating layer 190 is performed by, for example, CVD. The process of forming the mask material 191 and the mask material 192 is performed by, for example, applying a resist material and patterning by photolithography or the like.

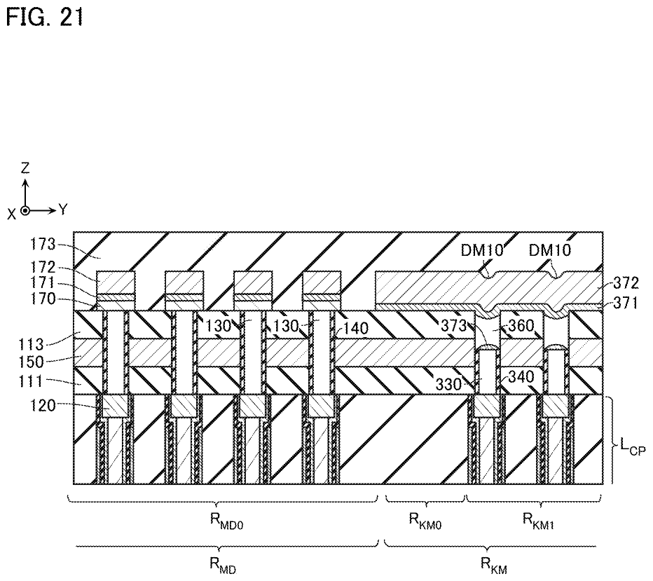

Next, for example, as illustrated in FIG. 21, the conductive layer 170, the conductive layer 171, and the conductive layer 172 are formed in the memory region R_{MD0}, and the conductive layer 371 and the conductive layer 372 are formed in the region R_{KM1}. This process is performed by, for example, RIE. Further, the insulating layer 173 filling an upper portion of these structures is formed, thus manufacturing the semiconductor device according to the embodiment.

### [Alignment Mark (1) in Formation of Bit Line BL]

In the process of forming the mask material 191 at the positions corresponding to the bit lines BL (FIG. 20), for matching of the position of the bit line BL with the position of the semiconductor layer 130 with high accuracy, it is necessary to perform an alignment of the wafer WF and a transfer mask or the like using an alignment mark including arrangement information of the semiconductor layer 130. As such an alignment mark the marks MK11, MK12, MK13, for example, as illustrated in FIG. 9 to FIG. 11 are used.

The marks MK11, MK12, MK13, and the like include the region R_{KM1} including the plurality of recessed portions DM10 formed by transferring the plurality of cavities 360 to the conductive layer 172′, and the approximately flat region R_{KM0}. These plurality of cavities 360 and plurality of semiconductor layers 130 are formed at once in the process of forming the opening TH10 (FIG. 13), and the positional relation therebetween is determined (for example, the distance Y₁₀ illustrated in FIG. 13 and FIG. 20). Accordingly, the position of the bit line BL can be matched with the position of the semiconductor layer 130 with high accuracy using the marks MK11, MK12, MK13, and the like which the arrangement information of the plurality of cavities 360 has inherited. Note that since the project light when recognizing the alignment mark passes through the insulating layer 190 and the mask material 192, these alignment marks are visible from above the structure illustrated in FIG. 20.

### Comparative Example

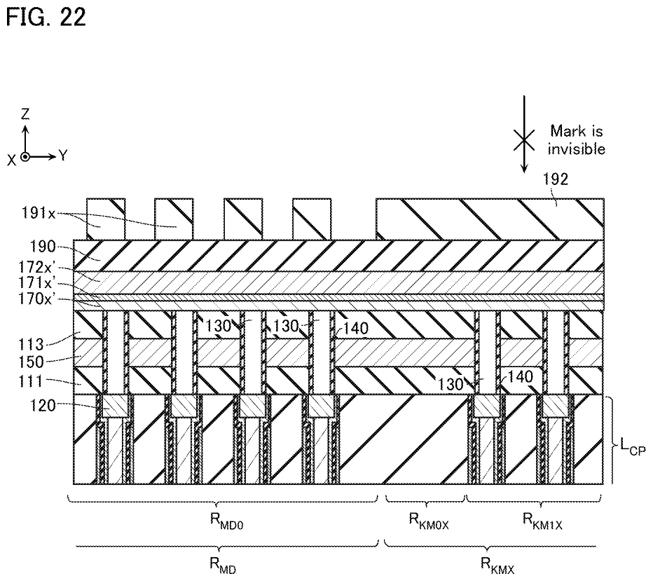

Next, with reference to FIG. 22, a semiconductor device according to a comparative example is described. FIG. 22 is a schematic cross-sectional view for describing a method of manufacturing the semiconductor device according to the comparative example, and corresponds to the process illustrated in FIG. 20.

The semiconductor device according to the comparative example includes a marked region R_{KMX} as illustrated in FIG. 22. The marked region R_{KMX} includes a region R_{KM0X} and a region R_{KM1X}. In the transistor layer L_{Tr} in the region R_{KM1X}, for example, the semiconductor layer 130 and the insulating layer 140 similar to those in the memory region R_{MD0} are provided as dummies. On upper surfaces in the region R_{KM1X} and the region R_{KM0X}, approximately flat conductive layer 170x′, conductive layer 171x′, and conductive layer 172x′ are provided.

In the manufacture of the semiconductor device according to the comparative example, when a process of forming a mask material 191x at positions corresponding to the bit lines BL (FIG. 22) is performed, it is necessary to visually perceive the alignment mark including the arrangement information of the semiconductor layer 130 from above the conductive layer 172x′ However, an upper surface of the conductive layer 172x′ is approximately flat, and is not formed with a recognizable alignment mark. In this case, an alignment mark including the arrangement information of the semiconductor layer 130 is formed below the conductive layer 172x′, and the alignment mark is visually perceived from above the conductive layer 172x′ in some cases. However, the conductive layer 172x′ contains, for example, tungsten (W). The conductive material, such as tungsten (W), is generally less likely to transmit the project light when recognizing the alignment mark. Therefore, it is difficult to match the position of the bit line BL with the position of the semiconductor layer 130 with high accuracy in some cases. Further, when the conductive layer 172x′ and the conductive layer 171x′ at the position corresponding to the marked region R_{KMX} are removed to make the alignment mark visible, the number of processes increases in some cases.

### [Effects]

In the manufacture of the semiconductor device according to the embodiment, the plurality of cavities 360 arranged in the Y-direction at the pitches P₁₀ are formed in the region R_{KM1} of the marked region R_{KM}, and the plurality of recessed portions DM10 self-conformably arranged in the Y-direction at the pitches P₁₀ are formed on upper portions of these plurality of cavities 360. The positions of the plurality of cavities 360 are determined simultaneously with the arrangement of the semiconductor layers 130 in the memory region R_{MD0} when the openings TH10a and the openings TH10b are formed (FIG. 13). Therefore, by using the alignment mark formed by the plurality of recessed portions DM10, the position of the bit line BL can be matched with the position of the semiconductor layer 130 with high accuracy. Accordingly, the semiconductor device that appropriately operates can be manufactured.

### [Modification 1 of First Embodiment]

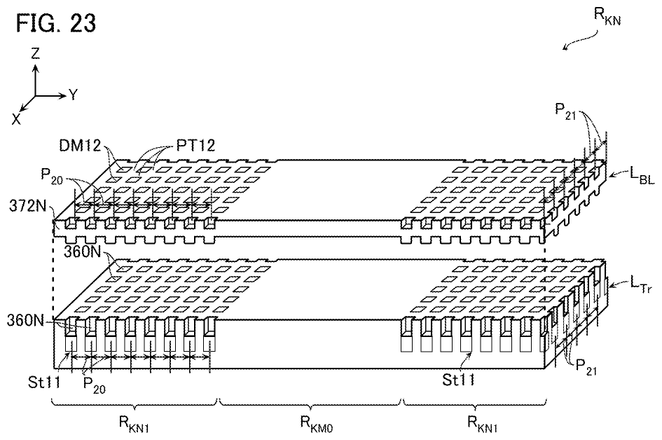

Next, with reference to FIG. 23, the modification 1 of the semiconductor device according to the first embodiment is described. FIG. 23 is a schematic perspective view illustrating apart of a configuration of a semiconductor device according to the modification. The semiconductor device according to the modification includes a marked region R_{N} instead of the marked region R_{KM}.

### [Exemplary Configuration of Marked Region R_{KN}]

The marked region R_{KN} is basically configured similarly to the marked region R_{KN}. However, the marked region R_{KN} includes a region R_{KN1} (FIG. 23) instead of the region R_{KM1} (FIG. 10).

FIG. 23 schematically illustrates a relation between the structure in the transistor layer L_{Tr} and the structure in the bit line layer L_{BL} in the two regions R_{KN1} adjacent in the Y-direction and the region R_{KM0} arranged therebetween. In the transistor layer L_{Tr} in the region R_{KN1}, a plurality of structures St11 are provided to be arranged in the Y-direction at pitches P₂₀. The structure St1 is not provided in the transistor layer L_{Tr} in the region R_{KM0}.

The structure St11 is, for example, basically configured similarly to the structure St10 (FIG. 8). However, the structure St1 has, for example, an approximately quadrangular prism shape different from the structure St10 (FIG. 6) having the approximately columnar shape. The structure St1 includes a cavity 360N instead of the cavity 360. The cavity 360N has an approximately square shape or an approximately rectangular shape in an XY cross-sectional surface.

The bit line layer L_{BL} in the marked region R_{KN} includes a conductive layer 372N (FIG. 23) instead of the conductive layer 372 (FIG. 10). The conductive layer 372N partially enters to the plurality of cavities 360N side during the film formation, and thus, the plurality of recessed portions DM12 having, for example, the approximately square shape or approximately rectangular shape are provided to be arranged in the Y-direction at the pitches P₂₀ at an upper surface of the conductive layer 372N in an XY cross-sectional surface. The plurality of recessed portions DM12 are provided at positions, for example, at least partially overlapping with the plurality of cavities 360N viewed in the Z-direction.

In the transistor layer L_{Tr} in the region R_{KN1} (FIG. 23), a plurality of the structures St11 may be provided to be arranged int the X-direction at pitches P₂₁. In this case, for example, as illustrated in FIG. 23, a plurality of the recessed portions DM12 are formed to be arranged in the Y-direction at the pitches P₂₀ and in the X-direction at the pitches P₂₁ on the upper surface of the conductive layer 372N. The pitch P₂₁ and the pitch P₂₀ may be same, or may be different.

In the transistor layer L_{Tr} in the region R_{KM0}(FIG. 23), the structure St11 is not provided. The upper surface of the conductive layer 372N is formed to be approximately flat, and is not formed with the recessed portion or the projecting portion.

For example, as illustrated in FIG. 23, at the upper surface of the conductive layer 372N in the region R_{KN1}, respective flat portions provided to be alternately arranged with the plurality of recessed portions DM12 in the X-direction or the Y-direction are referred to as a plurality of flat portions PT12. The plurality of recessed portions DM12 are provided at positions closer to the substrate than the plurality of flat portions PT12.

As described above, in the marked region R_{KN}, the plurality of recessed portions DM12 are arranged in at least one direction of the X-direction and the Y-direction at the upper surface of the conductive layer 372N in the region R_{KN1}, and the upper surface of the conductive layer 372N in the region R_{KM0} is formed to be approximately flat. When the conductive layer 372N in the marked region R_{KN} is observed from above, the respective regions R_{KN1} can be visually perceived as lines constituting the various marks in macroscopic view.

Note that lengths in the X-direction and the Y-direction of the structure St11 may be larger than lengths in the X-direction and the Y-direction of the transistor structure Tr10 in the memory region R_{MD0}.

### [Modification 2 of First Embodiment]

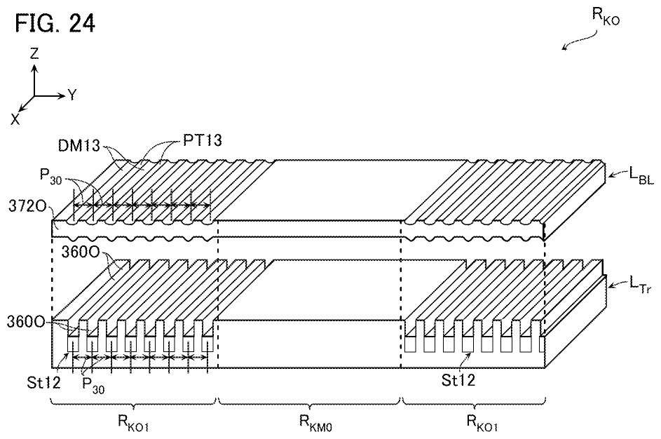

Next, with reference to FIG. 24, the modification 2 of the semiconductor device according to the first embodiment is described. FIG. 24 is a schematic perspective view illustrating a part of a configuration of a semiconductor device according to the modification. The semiconductor device according to the modification includes a marked region R_{KO} instead of the marked region R_{KM}.

### [Exemplary Configuration of Marked Region R_{KO}]

The marked region R_{KO} is basically configured similarly to the marked region R_{KM}. However, the marked region R_{KO} includes a region R_{KO1} (FIG. 24) instead of the region R_{KM1} (FIG. 10).

FIG. 24 schematically illustrates a relation between the structure in the transistor layer L_{Tr} and the structure in the bit line layer L_{BL} in the two regions R_{KO1} adjacent in the Y-direction and the region R_{KM0} arranged therebetween. In the transistor layer L_{Tr} in the region R_{KO1}, a plurality of structures St12 are provided to be arranged in the Y-direction at pitches P₃₀. The structure St12 is not provided in the transistor layer L_{Tr} in the region R_{KM0}.

The structure St12 is, for example, basically configured similarly to the structure St10 (FIG. 8). However, the structure St12 is different from the structure St10 (FIG. 6) having, for example, the approximately columnar shape, and has a structure extending in the X-direction and having a width approximately a half of the pitch P₃₀ in the Y-direction (FIG. 24). The structure St12 includes a cavity 360O instead of the cavity 360. Similarly to the structure St12, the cavity 360O also extends in the X-direction, and has a width approximately a half of the pitch P₃₀ in the Y-direction.

The bit line layer L_{BL} in the marked region R_{KO} includes a conductive layer 372O (FIG. 24) instead of the conductive layer 372 (FIG. 10). The conductive layer 372O partially enters to the plurality of cavities 360O side during the film formation, and thus, a plurality of recessed portions DM13, for example, extending in the X-direction and having the width approximately a half of the pitch P₃₀ in the Y-direction are provided to be arranged in the Y-direction at the pitches P₃₀ at an upper surface of the conductive layer 372O. The plurality of recessed portions DM13 are provided at positions, for example, at least partially overlapping with the plurality of cavities 360O viewed in the Z-direction.

In the transistor layer L_{Tr} in the region R_{KM0}, the structure St12 is not provided. The upper surface of the conductive layer 372O is formed to be approximately flat, and the recessed portion or the projecting portion is not formed.

For example, as illustrated in FIG. 24, at the upper surface of the conductive layer 372O in the region R_{KO1}, flat portions provided to be alternately arranged with the plurality of recessed portions DM13 in the Y-direction are referred to as a plurality of flat portions PT13. The plurality of recessed portions DM13 are provided at positions closer to the substrate than the plurality of flat portions PT13.

As described above, in the marked region R_{KO}, the plurality of recessed portions DM13 are arranged in the Y-direction at the upper surface of the conductive layer 372O in the region R_{KO1}, and the upper surface of the conductive layer 372O in the region R_{KM0} is formed to be approximately flat. When the conductive layer 372O in the marked region R_{KO} is observed from above, the respective regions R_{KO1} can be visually perceived as lines constituting the various marks in macroscopic view.

Note that a length in the Y-direction of the structure St12 may be larger than lengths in the X-direction and the Y-direction of the transistor structure Tr10 in the memory region R_{MD0}.

### [Modification 3 of First Embodiment]

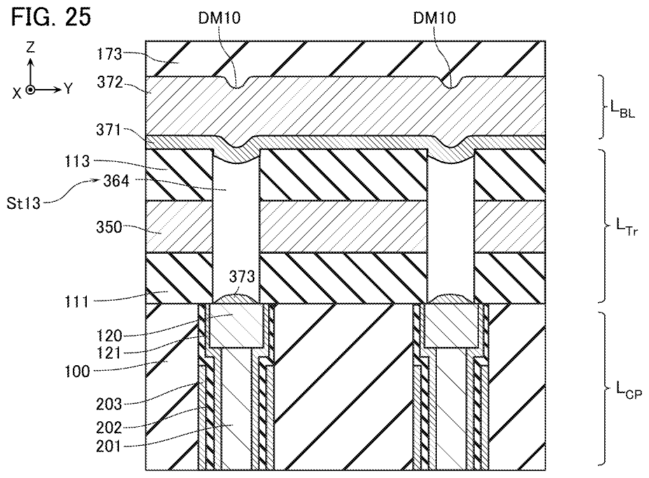

Next, with reference to FIG. 25, the modification 3 of the semiconductor device according to the first embodiment is described. FIG. 25 is a schematic cross-sectional view illustrating a part of a configuration of a semiconductor device according to the modification. The semiconductor device according to the modification includes a structure St13 instead of the structure St10.

### [Structure St13]

The structure St13 (FIG. 25) is basically configured similarly to the structure St10 (FIG. 8). However, the structure St13 is not provided with the semiconductor layer 330 or the insulating layer 340 as provided to the structure St10. The structure St13 is provided with a cavity 364 at a position at which the semiconductor layer 330, the insulating layer 340, and the cavity 360 of the structure St10 are provided. Note that in the structure St13, the conductive layer 373 may be provided on, for example, an upper surface of the conductive layer 120.

The cavity 364 has an inner wall surface surrounded by the insulating layer 113, the conductive layer 350, and the insulating layer 111. The cavity 364 has a bottom surface and an upper surface surrounded by the conductive layer 373 and the conductive layer 371. The cavity 364 is a space similar to the cavity 360.

Note that also in the structure St11 (FIG. 23) and the structure St12 (FIG. 24) of the modification 1 and the modification 2 of the first embodiment, a cavity similar to the cavity 364 may be provided at a position at which the semiconductor layer 330, the insulating layer 340, and the cavity 360N or the cavity 360O are to be provided without providing the semiconductor layer 330 or the insulating layer 340.

### Second Embodiment

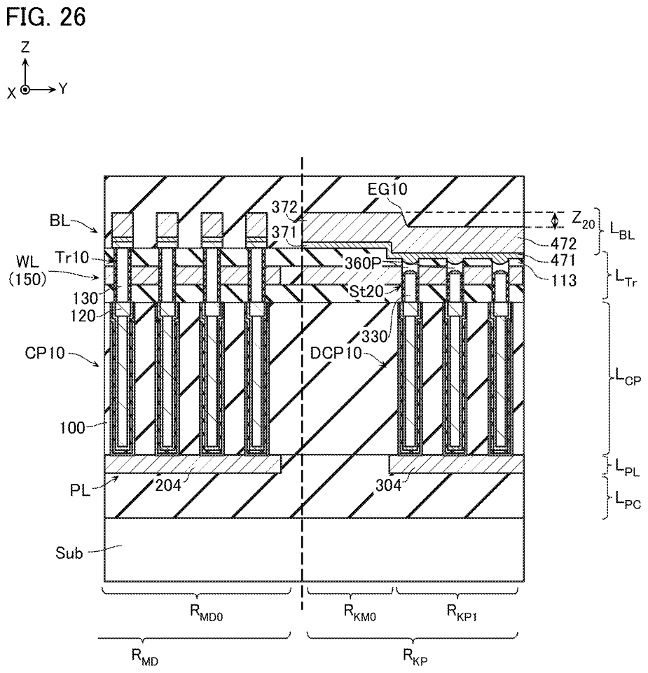

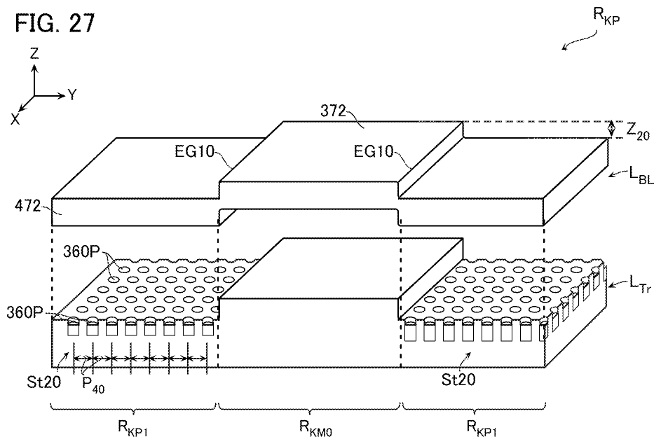

Next, with reference to FIG. 26 and FIG. 27, a semiconductor device according to the second embodiment is described. FIG. 26 is a schematic cross-sectional view for describing the semiconductor device according to the second embodiment. The semiconductor device according to the second embodiment is basically configured similarly to the semiconductor device according to the first embodiment. However, the semiconductor device according to the second embodiment includes a marked region R_{KP}, for example, as illustrated in FIG. 26 and FIG. 27 instead of the marked region R_{KM} (FIG. 4). In the following description, the same reference numerals are attached to configurations similar to those in the first embodiment, and the explanation will be omitted.

### [Structure of Marked Region R_{KP}]

The marked region R_{KP} includes the region R_{KM0} and a region R_{KP1}. The region R_{KP1} (FIG. 26) is basically configured similarly to the region R_{KM1} (FIG. 4). However, the insulating layer 113 in the region R_{KP1} has an upper surface provided at a position closer to the substrate Sub than the upper surface of the insulating layer 113 in the region R_{KM0} and the memory region R_{MD0}. Further, the transistor layer L_{Tr} in the region R_{KP1} includes a structure St20 instead of the structure St10 (FIG. 8). While the structure St20 is basically configured similarly to the structure St10, the structure St20 has a length in the Z-direction smaller than that of the structure St10. Additionally, the structure St20 includes a cavity 360P having a length in the Z-direction smaller than that of the cavity 360 instead of the cavity 360.

The bit line layer L_{BL} in the region R_{KP1} includes a conductive layer 471 and a conductive layer 472 provided on the upper surface of the insulating layer 113 in the order. The conductive layer 471 and the conductive layer 472 are basically configured similarly to the conductive layer 371 and the conductive layer 372 in the region R_{KM1}. However, the conductive layer 472 provided in the region R_{KP1} has an upper surface provided at a position closer to the substrate Sub than the upper surface of the conductive layer 372 provided in the region R_{KM0} by a width Z₂₀. Between the region R_{KM0} and the region R_{KP1}, a corner portion EG10 is provided.

### [Exemplary Configuration of Marked Region R_{KP}]

Next, with reference to FIG. 9 and FIG. 27, the exemplary configuration of the marked region R_{KP} is described. FIG. 27 is a schematic perspective view illustrating an enlarged region corresponding to the region D illustrated in FIG. 9.

The marked region R_{KP} includes the mark MK11, the mark MK12, and the mark MK13 similar to those of the first embodiment, for example, as illustrated in FIG. 9. In the marked region R_{KP} excluding the positions where the regions R_{KP1} are provided, the region R_{KM0} is provided.

FIG. 27 schematically illustrates a relation between the structure in the transistor layer L_{Tr} and the structure in the bit line layer L_{BL} in the two regions R_{KP1} adjacent in the Y-direction and the region R_{KM0} arranged therebetween.

There is a step as illustrated in FIG. 27 between the upper surface of the conductive layer 472 in the region R_{KP1} and the upper surface of the conductive layer 372 in the region R_{KM0}, and thus the corner portion EG10 is provided along a boundary between these region R_{KP1} and region R_{KM0}.

Between the corner portion EG10 and the region excluding the corner portion EG10, reflection and diffusion characteristics to a project light from above are different. Accordingly, when the conductive layer 372 in the marked region R_{KP} is observed from above, the respective regions R_{KP1} surrounded by the corner portions EG10 can be visually perceived as lines constituting the various marks.

In the transistor layer L_{Tr} in the region R_{KP1}, as illustrated in FIG. 27, a plurality of the structures St20 are provided to be arranged in the Y-direction at pitches P₄₀. Each of the structures St20 includes the cavity 360P in its upper portion, and these plurality of cavities 360P are similarly arranged in the Y-direction at the pitches P₄₀.

### [Manufacturing Method of Second Embodiment]

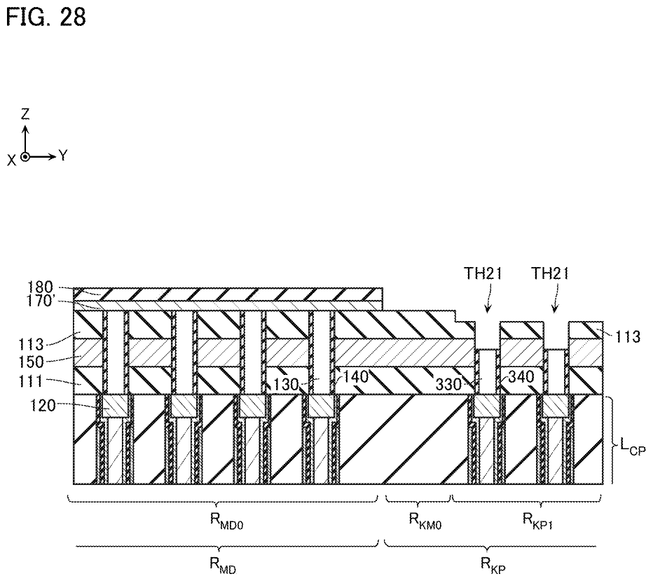

Next, with reference to FIG. 28 to FIG. 31, a method of manufacturing the semiconductor device according to the second embodiment is described.

The semiconductor device according to the second embodiment is basically manufactured similarly to the semiconductor device according to the first embodiment. However, in the method of manufacturing the semiconductor device according to the embodiment, in a process corresponding to the process described with reference to FIG. 16, as illustrated in FIG. 28, a part of the insulating layer 113 in the region R_{KP1} is removed together with a part of the insulating layer 180′, a part of the conductive layer 170″, a part of the semiconductor layer 330′, and a part of the insulating layer 340′ in the region R_{KP1}. Note that in the region R_{KP1}, in the process of partially removing the semiconductor layer 330′ and the insulating layer 340′ to form a plurality of openings TH21, the insulating layer 113 is removed also from insides of the openings TH21. This makes the upper surface of the insulating layer 113 in the region R_{KP1} be positioned to be closer to the substrate Sub than the upper surface of the insulating layer 113 in the region R_{KM0} and the memory region R_{MD0}. This process is performed by, for example, RIE.

Next, a process corresponding to the process described with reference to, for example, FIG. 17 is performed to remove the insulating layer 180.

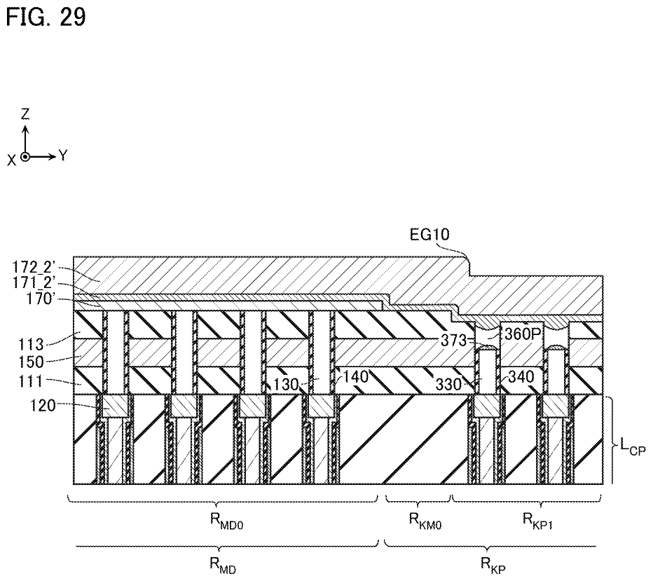

Next, for example, as illustrated in FIG. 29, a conductive layer 171_2′ and a conductive layer 172_2′ are formed on the upper surface of the conductive layer 170′ in the memory die region R_{MD} and the upper surface of the insulating layer 113 and upper portions of the openings TH21 in the marked region R_{KP}. The conductive layer 171_2′ contains, for example, a material similar to that of the conductive layer 171 and the conductive layer 371. The conductive layer 172_2′ contains, for example, a material similar to that of the conductive layer 172 and the conductive layer 372. Through this process, an upper surface of the conductive layer 172_2′ in the region R_{KP1} is formed at a position closer to the substrate Sub than the upper surface of the conductive layer 172_2′ in the region R_{KM0} and the memory region R_{MD0}, and the corner portion EG10 is formed between the region R_{KM0} and the region R_{KP1}. Further, in this process, an upper surface of the conductive layer 171_2′ is formed to be approximately flat above a portion at which the opening TH21 is provided. This process is performed by, for example, ALD or CVD.

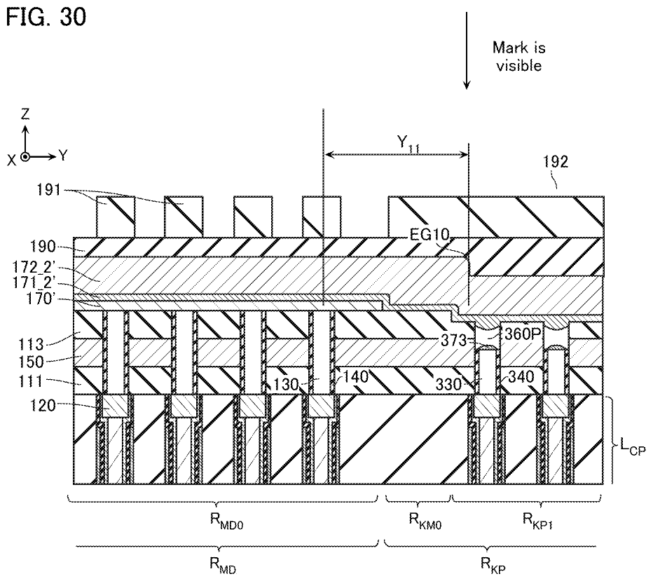

Next, for example, as illustrated in FIG. 30, the insulating layer 190 is formed on the upper surface of the conductive layer 172_2′ similarly to the process illustrated in FIG. 20. Further, the mask material 191 is formed at positions corresponding to the bit lines BL in the memory region R_{MD0} at the upper surface of the insulating layer 190. The mask material 192 that covers the marked region R_{KP} is formed in the region R_{KP1}.

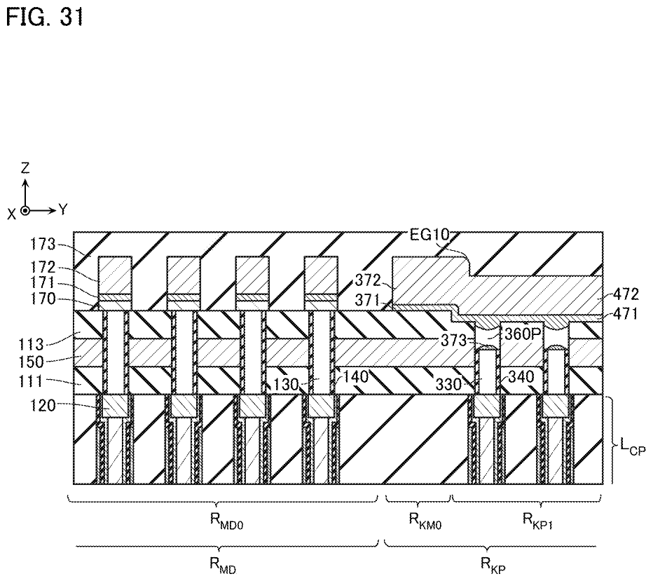

Next, for example, as illustrated in FIG. 31, the conductive layer 170, the conductive layer 171, and the conductive layer 172 are formed in the memory region R_{MD0}. Further, the conductive layer 471 and the conductive layer 472 are formed in the region R_{KP1}. The conductive layer 371 and the conductive layer 372 are formed in the region R_{KM0}. This process is performed by, for example, RIE. Further, the insulating layer 173 filling the upper portion of these structures is formed, thus manufacturing the semiconductor device according to the embodiment.

### [Alignment Mark (2) in Formation of Bit Line BL]

In the manufacturing process (FIG. 30) of forming the mask material 191 at the positions corresponding to the bit lines BL according to the embodiment, as the alignment mark, for example, similarly to the first embodiment, the marks MK11, MK12, MK13, and the like (FIG. 9) visually perceivable from above are used.

For the marks MK11, MK12, MK13, and the like, the corner portion EG10 is formed between the region R_{KP1} including a plurality of the structures St20 (FIG. 26) and the region R_{KM0}. The position at which the corner portion EG10 is formed corresponds to the positions of the structures St20 at an outermost periphery of the region R_{KP1}. The structures St20 at the outermost periphery and a plurality of the semiconductor layers 130 are formed at once in the process of forming the opening TH10 (FIG. 13), and the positional relation therebetween is determined (for example, a distance Y₁₁ illustrated in FIG. 30). Accordingly, the position of the bit line BL can be matched with the position of the semiconductor layer 130 with high accuracy using the marks MK11, MK12, MK13, and the like which the arrangement information of the structure St20 has inherited.

### [Modification of Second Embodiment]

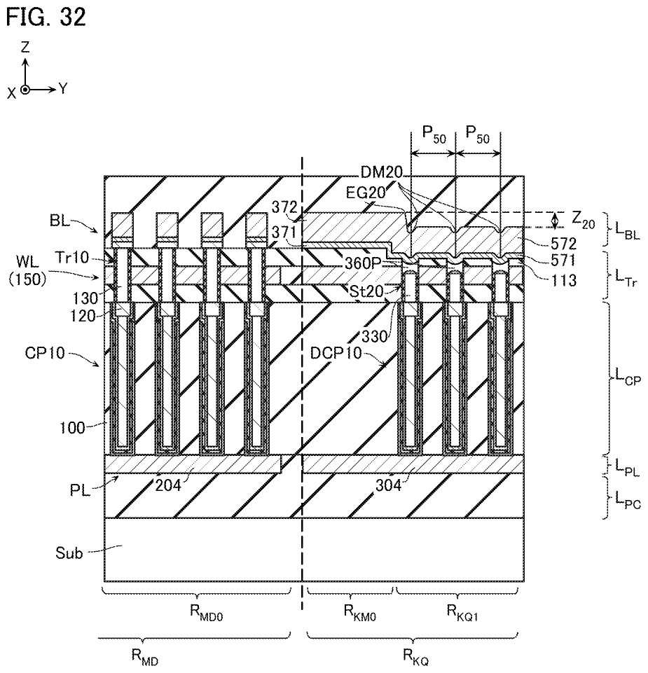

Next, with reference to FIG. 32, the modification of the semiconductor device according to the second embodiment is described. FIG. 32 is a schematic cross-sectional view illustrating a part of a configuration of the semiconductor device according to the modification. The semiconductor device according to the modification includes a marked region R_{KQ} instead of the marked region R_{KP}.

### [Exemplary Configuration of Marked Region R_{KQ}]

The marked region R_{KQ} is basically configured similarly to the marked region R_{KP}. However, the marked region R_{KQ} includes a region R_{KQ1} (FIG. 32) instead of the region R_{KP1} (FIG. 26).

### [Structure of Region R_{KQ1}]

The region R_{KQ1} (FIG. 32) is basically configured similarly to the region R_{KP1} (FIG. 26). However, the bit line layer L_{BL} in the region R_{KQ1} includes a conductive layer 571 and a conductive layer 572 provided on the upper surface of the insulating layer 113 in the order. The conductive layer 572 in the region R_{KQ1} has an upper surface that is not approximately flat and provided with a plurality of recessed portions DM20 arranged in the Y-direction at pitches P₅₀.

In the marked region R_{KQ}, a corner portion EG20 is provided at an outer periphery portion of the region R_{KQ1}, and the plurality of recessed portions DM20 are arranged in at least one direction of the X-direction and the Y-direction at the upper surface of the conductive layer 572. Meanwhile, the upper surface of the conductive layer 372 in the region R_{KM0} is formed to be approximately flat. Between the upper surface of the region R_{KM1}, the corner portion EG20, and the upper surface of the region R_{KQ1}, reflection and diffusion characteristics to a project light from above are different. Accordingly, when the conductive layer 372 and the conductive layer 572 in the marked region R_{KQ} are observed from above, the respective regions R_{KQ1} can be visually perceived as lines constituting the various marks in macroscopic view.

### [Manufacturing Method of Modification of Second Embodiment]

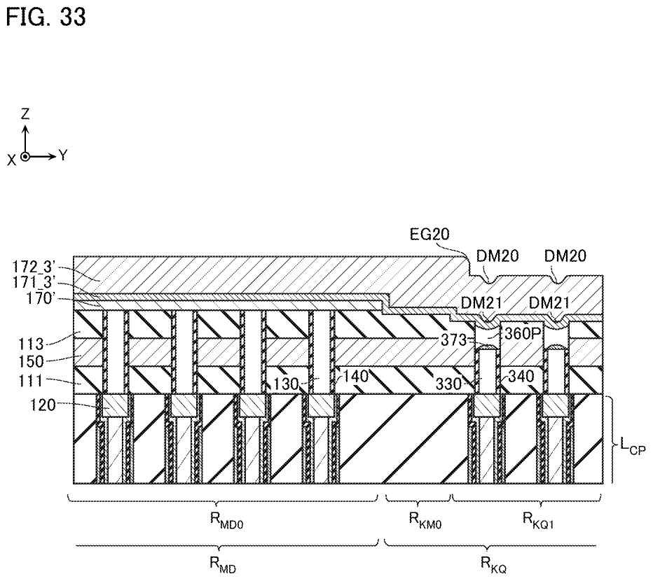

Next, with reference to FIG. 33, a method of manufacturing the semiconductor device according to the modification of the second embodiment is described.

The semiconductor device according to the modification of the second embodiment is basically manufactured similarly to the semiconductor device according to the first embodiment. However, in the method of manufacturing the semiconductor device according to the embodiment, in a process corresponding to the process described with reference to FIG. 29, for example, as illustrated in FIG. 33, a conductive layer 171_3′ and a conductive layer 172_3′ are formed on the upper surface of the conductive layer 170′ in the memory die region R_{MD} and the upper surface of the insulating layer 113 and the upper portions of the openings TH21 in the marked region R_{KQ}. The conductive layer 171_3′ contains, for example, a material similar to that of the conductive layer 171. The conductive layer 172_3′ contains, for example, a material similar to that of the conductive layer 172. Note that in this process, as illustrated in FIG. 33, while a part of the conductive layer 171_3′ enters inside the opening TH21, the opening TH21 is not completely filled with the conductive layer 171_3′, and the upper portion of the opening TH21 is closed by the conductive layer 171_3′. Thus, recessed portions DM21 of the conductive layer 171_3′ and the recessed portions DM20 of the conductive layer 172_3′ are formed above a portion at which the opening TH21 is provided. Further, an upper surface of the conductive layer 172_3′ in the region R_{KQ1} is formed at a position closer to the substrate Sub than an upper surface of the conductive layer 172_3′ in the region R_{KM0} and the memory region R_{MD0}, and the corner portion EG20 is formed between the region R_{KM0} and the region R_{KQ1}. This process is performed by, for example, ALD or CVD.

### Other Embodiments

The semiconductor devices according to the first embodiment and the second embodiment have been described above. However, the semiconductor devices according to these embodiments are merely examples, and the specific configuration, operation, and the like are adjustable as necessary.

For example, in the above description, the example in which the capacitor Cap is connected to the select transistor ST is described. In this example, the shape, the structure, and the like of the capacitor Cap can be adjusted as necessary.

Additionally, in the above description, the example in which the capacitor Cap is employed as the memory portion connected to the select transistor ST is described. However, the memory portion need not be the capacitor Cap. For example, the memory portion may contain any material including a ferroelectric material, a ferromagnet material, and a chalcogen material such as and GeSbTe, and may store data using the characteristics of these materials. For example, in any of the structures described above, any of these materials may be contained in the insulating layer between the electrodes forming the capacitor Cap.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate where a first region and a second region are provided;
a transistor layer spaced from the substrate; and
a first wiring layer farther from the substrate than the transistor layer, wherein
the transistor layer includes, in the first region:
a plurality of first oxide semiconductor layers extending in a first direction intersecting with a surface of the substrate and being arranged in a second direction intersecting with the first direction;
a first wiring extending in the second direction and being opposed to the plurality of first oxide semiconductor layers; and
a plurality of gate insulating films provided between the plurality of first oxide semiconductor layers and the first wiring,
the first wiring layer includes a plurality of second wirings arranged in the second direction and electrically connected to respective one ends of the plurality of first oxide semiconductor layers, in the first region,
the transistor layer includes a plurality of cavities arranged in the second direction or a third direction intersecting with the first direction and the second direction at first pitches, in the second region,
the first wiring layer includes a first conductive layer in the second region, and
a plurality of recessed portions arranged in the second direction or the third direction at the first pitches are provided on a surface on a side far from the substrate of the first conductive layer.

2. The semiconductor device according to claim 1, wherein
the plurality of recessed portions are provided at positions overlapping with the plurality of cavities viewed in the first direction.

3. The semiconductor device according to claim 1, wherein
the surface on the side far from the substrate of the first conductive layer includes:
a plurality of first parts arranged at the first pitches in the second direction or the third direction; and
a plurality of second parts alternately arranged with the plurality of first parts in the second direction or the third direction, and
the plurality of first parts are closer to the substrate than the plurality of second parts in the first direction.

4. The semiconductor device according to claim 3, wherein
the plurality of first parts are provided at positions overlapping with the plurality of cavities viewed in the first direction.

5. The semiconductor device according to claim 1, wherein
the plurality of cavities are arranged at the first pitches in the second direction, and arranged at second pitches in the third direction, and
on the surface on the side far from the substrate of the first conductive layer, the recessed portions corresponding to the first pitches are provided in the second direction, and recessed portions corresponding to the second pitches are provided in the third direction.

6. The semiconductor device according to claim 1, wherein
the transistor layer includes a plurality of second oxide semiconductor layers arranged at the first pitches in the second direction or the third direction corresponding to the plurality of cavities, in the second region,
one end portions on a substrate side of the plurality of first oxide semiconductor layers and one end portions on the substrate side of the plurality of second oxide semiconductor layers are provided at positions approximately equal from the substrate, and
lengths in the first direction of the plurality of second oxide semiconductor layers are smaller than lengths in the first direction of the plurality of first oxide semiconductor layers.

7. The semiconductor device according to claim 1, comprising
a capacitor layer between the substrate and the transistor layer, wherein
the capacitor layer includes a plurality of first structures electrically connected to the respective plurality of first oxide semiconductor layers, in the first region,
each of the plurality of first structures includes:
a first electrode extending in the first direction and being electrically connected to the first oxide semiconductor layer; and
a second electrode extending in the first direction and being opposed to the first electrode.

8. The semiconductor device according to claim 1, comprising
a capacitor layer between the substrate and the transistor layer, wherein
the capacitor layer includes a plurality of capacitors electrically connected to the respective plurality of first oxide semiconductor layers, in the first region.

9. The semiconductor device according to claim 1, wherein
the surface on the side far from the substrate of the first conductive layer is closer to the substrate than surfaces on the side far from the substrate of the plurality of second wirings.

10. A semiconductor device comprising:
a substrate where a first region and a second region are provided;
a transistor layer spaced from the substrate; and
a first wiring layer farther from the substrate than the transistor layer, wherein
the transistor layer includes, in the first region:
a plurality of first oxide semiconductor layers extending in a first direction intersecting with a surface of the substrate and being arranged in a second direction intersecting with the first direction;
a first wiring extending in the second direction and being opposed to the plurality of first oxide semiconductor layers; and
a plurality of gate insulating films provided between the plurality of first oxide semiconductor layers and the first wiring,
the first wiring layer includes a plurality of second wirings arranged in the second direction and electrically connected to respective one ends of the plurality of first oxide semiconductor layers, in the first region,
the transistor layer includes a plurality of cavities arranged at first pitches in the second direction or a third direction intersecting with the first direction and the second direction, in the second region,
the first wiring layer includes a first conductive layer in the second region, and
a surface on a side far from the substrate of the first conductive layer is closer to the substrate than surfaces on the side far from the substrate of the plurality of second wirings.

11. The semiconductor device according to claim 10, wherein
the plurality of cavities are arranged at the first pitches in the second direction, and arranged at second pitches in the third direction, and
on the surface on the side far from the substrate of the first conductive layer, recessed portions corresponding to the first pitches are provided in the second direction, and recessed portions corresponding to the second pitches are provided in the third direction.

12. The semiconductor device according to claim 10, wherein
the transistor layer includes a plurality of second oxide semiconductor layers arranged at the first pitches in the second direction or the third direction corresponding to the plurality of cavities, in the second region,
one end portions on the substrate side of the plurality of first oxide semiconductor layers and one end portions on the substrate side of the plurality of second oxide semiconductor layers are provided at positions approximately equal from the substrate, and
lengths in the first direction of the plurality of second oxide semiconductor layers are smaller than lengths in the first direction of the plurality of first oxide semiconductor layers.

13. The semiconductor device according to claim 10, comprising
a capacitor layer between the substrate and the transistor layer, wherein
the capacitor layer includes a plurality of first structures electrically connected to the respective plurality of first oxide semiconductor layers, in the first region,
each of the plurality of first structures includes:
a first electrode extending in the first direction and being electrically connected to the first oxide semiconductor layer; and
a second electrode extending in the first direction and being opposed to the first electrode.

14. The semiconductor device according to claim 10, comprising
a capacitor layer between the substrate and the transistor layer, wherein
the capacitor layer includes a plurality of capacitors electrically connected to the respective plurality of first oxide semiconductor layers, in the first region.
